(19) United States
(12) Patent Application Publication
(10) Pub. No.: US 2025/0140590 A1
(43) Pub. Date: May 1, 2025

(54) Teaching Method and Substrate Processing System

(71) Applicant: Tokyo Electron Limited, Tokyo (JP)

(72) Inventors: Toshiaki KODAMA, Yamanashi (JP); Tatsuru Okamura, Miyagi (JP)

(21) Appl. No.: 18/921,728

(22) Filed: Oct. 21, 2024

(30) Foreign Application Priority Data
Oct. 31, 2023 (JP) 2023-186849

(51) Int. Cl. H01L 21/68; G05B 19/418; H01L 21/687

(52) U.S. Cl. CPC H01L 21/68; G05B 19/4189; H01L 21/68707; G05B 2219/36106

(57) ABSTRACT

Provided is a teaching method for teaching a transfer position of a consumable member in a cassette included in a substrate processing system, the substrate processing system having a transfer device configured to transfer the consumable member, and a storage module where the cassette accommodating a plurality of the consumable members is set; the teaching method comprising the steps of: (A) recognizing setting of the cassette in the storage module; and (B) after the step (A), detecting the cassette by a sensor of the transfer device and calculating three-dimensional coordinates of the cassette based on detection information of the sensor.

### CROSS-REFERENCE TO RELATED APPLICATIONS

This application claims priority to Japanese Patent Application No. 2023-186849 filed on Oct. 31, 2023, the entire contents of which are incorporated herein by reference.

### TECHNICAL FIELD

The present disclosure relates to a teaching method and a substrate processing system.

### BACKGROUND

Japanese Laid-open Patent Publication No. 2022-2255 discloses a substrate processing system in which a storage module that stores consumable members used during substrate processing is connected to a vacuum transfer module (vacuum transfer chamber). The substrate processing system controls a transfer robot (robot arm) of the vacuum transfer module to unload the consumable members from the storage module and to load the consumable members into a processing module. Further, the substrate processing system controls the transfer robot to unload used consumable members from the processing module and to load the used consumable members into the storage module.

### SUMMARY

The present disclosure provides a technique that allows stable loading and unloading of consumable members into and from a storage module.

In accordance with an aspect of the present disclosure, there is provided a teaching method for teaching a transfer position of a consumable member in a cassette included in a substrate processing system, the substrate processing system having a transfer device configured to transfer the consumable member, and a storage module where the cassette accommodating a plurality of the consumable members is set; the teaching method comprising the steps of: (A) recognizing setting of the cassette in the storage module; and (B) after the step (A), detecting the cassette by a sensor of the transfer device and calculating three-dimensional coordinates of the cassette based on detection information of the sensor.

### BRIEF DESCRIPTION OF THE DRAWINGS

FIG. 1 is a schematic plan view showing an overall configuration example of a substrate processing system according to an embodiment.

FIG. 2 is an enlarged plan view showing a substrate and a fork of a vacuum transfer device.

FIG. 3A is a side view explaining the principle of teaching a transfer position of the vacuum transfer device.

FIG. 3B is a plan view explaining the principle of teaching the transfer position of the vacuum transfer device.

FIG. 4 is a side cross-sectional view showing a storage module of the substrate processing system.

FIG. 5 is a flowchart showing a process flow of a teaching method according to an embodiment.

FIG. 6 is a flowchart showing a process flow of a cassette position detection process of the teaching method.

FIG. 7A is a side view showing an operation of detecting a bottom plate by a fork-side sensor.

FIG. 7B is a plan view showing an operation of detecting an opening of the bottom plate by the fork-side sensor.

FIG. 7C is a plan view showing an operation of detecting a height position of the bottom plate by the fork-side sensor.

FIG. 8A is a side view showing an operation of detecting a top plate by the fork-side sensor.

FIG. 8B is a plan view showing an operation of detecting a height position of the top plate by the fork-side sensor.

### DETAILED DESCRIPTION

Hereinafter, embodiments of the present disclosure will be described with reference to the accompanying drawings. Like reference numerals will be given to like parts throughout the drawings, and redundant description thereof may be omitted.

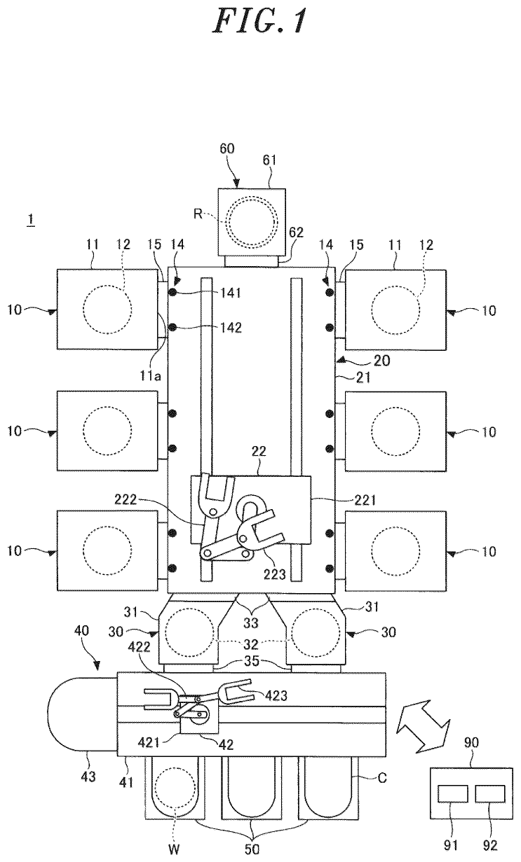

FIG. 1 is a schematic plan view showing an overall configuration example of a substrate processing system 1 according to an embodiment. As shown in FIG. 1, the substrate processing system 1 is a multi-chamber type semiconductor manufacturing apparatus including multiple (six) processing modules 10. Each processing module 10 performs substrate processing such as film formation, etching, cleaning, or the like on a substrate W transferred thereinto. Further, the substrate processing system 1 includes, in addition to the processing modules 10, a vacuum transfer module 20, multiple load-lock modules 30, an atmospheric transfer module 40, a load port 50, a storage module 60, and a controller 90.

The substrate W is loaded/unloaded between the vacuum transfer module 20 and each processing module 10, and the above-described substrate processing is performed in a state where the substrate W is loaded into each processing module 10. The number of processing modules 10 of the substrate processing system 1 is not particularly limited. Further, the processing modules 10 may perform the same processing, or some of them or all of them may perform different types of processing. The substrate processing system 1 may be configured to perform plasma processing in some or all of the processing modules 10.

Each processing module 10 has a processing chamber 11 accommodating a substrate W, and a substrate support 12 on which the substrate W is placed in the processing chamber 11. The substrate support 12 has a lifter (not shown) for raising and lowering the substrate W, and receives and delivers the substrate W in cooperation with a vacuum transfer device 22 of the vacuum transfer module 20 to be described later.

Further, the substrate processing system 1 includes a connection part 15 that connects the vacuum transfer module 20 and the processing chamber 11 of each processing module 10, and a processing module-side sensor 14 for detecting the substrate W. The connection part 15 has therein a gate valve (not shown) for opening and closing an opening 11a of the processing chamber 11. In each processing module 10, the substrate W can be transferred to the processing chamber 11 via the connection part 15 by opening the gate valve, and the pressure in the processing chamber 11 can be reduced to an appropriate vacuum atmosphere by closing the gate valve.

The processing module-side sensor 14 detects the outer edge of the substrate W when the substrate W is transferred between each processing module 10 and the vacuum transfer module 20, and transmits the detection information to the controller 90. The controller 90 can calculate the center position of the substrate W based on the detection information of each processing module-side sensor 14, and can also recognize the deviation of the center position of the substrate W transferred to the vacuum transfer device 22. The processing module-side sensor 14 is disposed, e.g., at a position adjacent to the opening 11a of each processing module 10 in the vacuum transfer module 20. Further, the processing module-side sensor 14 may be provided inside the connection part 15 or may be provided at a position adjacent to the opening 11a in the processing module 10.

The processing module-side sensor 14 has two detectors 141 and 142 for detecting whether or not the substrate W exists. For example, each of the detectors 141 and 142 includes a light emitting part (not shown) for emitting measurement light, and a light receiving part (not shown) for receiving light from the light emitting part with a route through which the substrate W passes interposed therebetween. The detectors 141 and 142 detect the presence of the substrate W when the measurement light is blocked by the passage of the substrate W. The two detectors 141 and 142 are arranged in a direction parallel to the opening 11a, and they are disposed such that the distance therebetween becomes shorter than the diameter of the substrate W. The method for detecting the position of the substrate W using the processing module-side sensor 14 is substantially the same as the method for detecting the position of the substrate W using fork-side sensors 227 of the vacuum transfer device 22 to be described later.

The vacuum transfer module 20 of the substrate processing system 1 includes a transfer chamber 21 connected to the respective processing modules 10 and the respective load-lock modules 30, and a vacuum transfer device 22 for transferring the substrate W disposed in the transfer chamber 21. Further, the vacuum transfer module 20 may include a plurality of transfer regions (or transfer chambers 21), each having the vacuum transfer device 22, and a path region that connects the transfer regions, and may be configured to transfer the substrate W from one transfer region to another transfer region via the path region.

The transfer chamber 21 is formed in a rectangular shape in plan view, and has a transfer space 21s that is airtightly sealed from the outside. The transfer space 21s is depressurized to a vacuum atmosphere by a vacuum suction device (not shown). In the substrate processing system 1 according to the embodiment, three processing modules 10 are connected to each of a pair of long sides of the transfer chamber 21. Further, in the substrate processing system 1, two load-lock modules 30 are connected to one short side of the transfer chamber 21.

The vacuum transfer device 22 moves in the transfer space 21s under the control of the controller 90 to transfer the substrate W. For example, the vacuum transfer device 22 transfers the substrate W from an appropriate load-lock module 30 to an appropriate processing module 10. Further, under the control of the controller 90, the vacuum transfer device 22 transfers the substrate W from an appropriate processing module 10 to an appropriate load-lock module 30. Further, the vacuum transfer device 22 may transfer the substrate W between two processing modules 10.

The vacuum transfer device 22 transfers, in addition to the substrate W, consumable members used in the processing module 10. In the embodiment, the consumable member transferred by the vacuum transfer device 22 is a ring R disposed at the substrate support 12 of the processing module 10. The ring R may be, e.g., an edge ring (or focus ring) disposed around the outer edge of the substrate W, or a cover ring disposed around the edge ring (or focus ring). However, the consumable member transferred by the vacuum transfer device 22 is not limited to the ring R, and may be, e.g., an upper electrode of the processing module 10 that is consumed by plasma processing, or a member in the processing chamber 11.

The vacuum transfer device 22 has a base 221 capable of moving in the longitudinal direction of the transfer chamber 21, a plurality of arms 222 capable of rotating, extending and contracting, and moving up and down with respect to the base 221, and a fork (end effector) 223 disposed at the arm 222 on the distal end side. Although FIG. 1 illustrates the vacuum transfer device 22 having two forks 223, the vacuum transfer device 22 is not limited thereto, and may have a configuration including one or three or more forks 223.

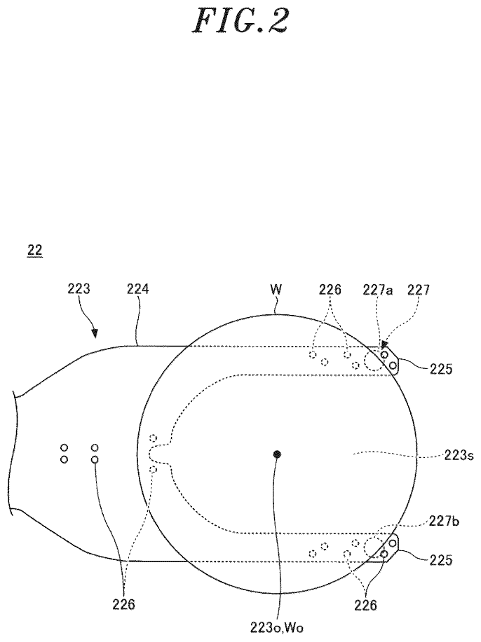

FIG. 2 is an enlarged plan view of the substrate W and the fork 223 of the vacuum transfer device 22. As shown in FIG. 2, the vacuum transfer device 22 supports the substrate W on the upper surface of the fork 223, and transfers the substrate W by appropriately operating the base 221 and the arms 222 shown in FIG. 1. Also in the case of transferring the ring R, the vacuum transfer device 22 supports the ring R on the upper surface of the fork 223.

The fork 223 has a base plate portion 224 connected to the arm 222 on the distal end side, and a pair of support plate portions 225 extending while being branched from the base plate portion 224. The base plate portion 224 and the pair of support plate portions 225 are integrally molded with each other and continuous in the horizontal direction, thereby forming a U-shape in plan view. The pair of support plate portions 225 are parallel to each other, and have the same length. The fork 223 has a concave space 223s surrounded by the base plate part 224 and the pair of support plate portions 225. The concave space 223s is opened at the tip ends (extension ends) of the pair of support plate portions 225.

Further, the fork 223 has a plurality of pads 226 on the upper surfaces of the base plate portion 224 and the support plate portion 225. For example, the plurality of pads 226 are disposed at intermediate positions in the width direction of the base plate portion 224, and are also disposed on the tip end sides of the pair of support plate portions 225 to directly support the positions of the substrate W in three directions. The plurality of pads 226 may be made of a material (such as an elastomer or the like) having appropriate frictional force and elasticity. Further, the fork 223 may have a holding device such as a suction mechanism, an electrostatic attraction mechanism, or a mechanical locking mechanism for holding the substrate W using the plurality of pads 226 (or instead of the plurality of pads 226).

In the case of supporting the substrate W with the fork 223, the vacuum transfer device 22 moves the fork 223 such that a center position Wo of the substrate W coincides with a reference position 2230 that is preset at the fork 223. The position where the fork 223 of the vacuum transfer device 22 moves to support or place the substrate W corresponds to “transfer position” of the substrate W. Accordingly, the vacuum transfer device 22 can stably support the substrate W such that the reference position 2230 of the fork 223 coincides with the center position Wo of the substrate W, and can transfer the substrate W to a desired transfer position.

The fork 223 has the fork-side sensors 227 for detecting the substrate W as a transfer object on the surface (bottom surface) opposite to the surface supporting the substrate W. The fork-side sensor 227 according to the embodiment has multiple (two in FIG. 2) detectors 227a and 227b. The detectors 227a and 227b are disposed near the extension ends (tip ends of the fork 223) of the pair of support plate portions 225, respectively, and detect an object disposed below (opposed to) the fork 223 in the vertical direction. Further, the fork-side sensors 227 are connected to the controller 90 to be communicable therewith, perform detection under the control of the controller 90, and transmit the detection information to the controller 90.

For example, each fork-side sensor 227 may be a displacement sensor for optically measuring the distance from the fork 223 to the object. In this case, each of the detectors 227a and 227b of the fork-side sensors 227 has a light emitting part and a light receiving part, and measures the distance to the object based on the light intensity or wavelength of the detection light emitted by the light emitting part and reflected by the object. Alternatively, the detectors 227a and 227b may be configured to detect the change in the height of the object based on the light intensity by an on/off signal.

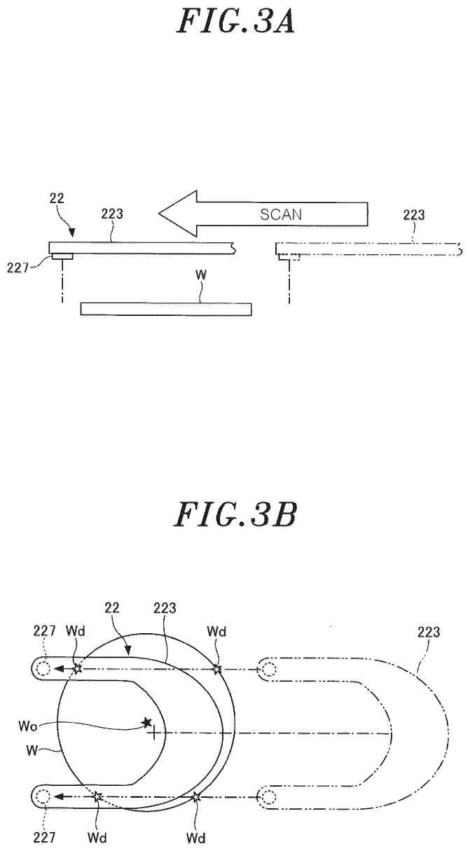

FIG. 3A is a side view explaining the principle of teaching the transfer position of the vacuum transfer device 22. FIG. 3B is a plan view explaining the principle of teaching the transfer position of the vacuum transfer device 22. As shown in FIGS. 3A and 3B, in the teaching method, the fork-side sensors 227 of the vacuum transfer device 22 are used to detect multiple outer edge positions of the substrate W, thereby calculating the center position Wo of the substrate W from the multiple outer edge positions. Specifically, the controller 90 detects (scans) the substrate W with the fork-side sensors 227 while sliding the vacuum transfer device 22 horizontally and linearly above the substrate W in the vertical direction. In this case, the linear movement of the vacuum transfer device 22 is controlled such that the reference position 2230 of the fork 223 passes through a preset design position.

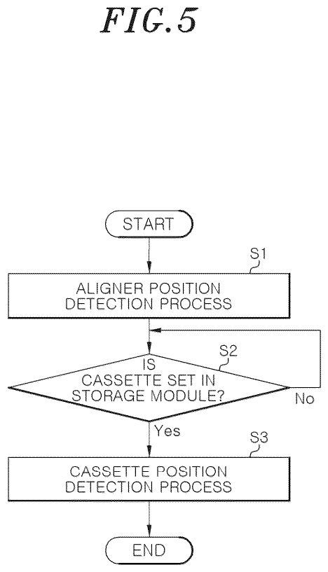

The fork-side sensors 227 disposed near the tip ends of the support plate portions 225 of the vacuum transfer device 22 detect the outer edge of the substrate W while passing through a position above the substrate W. The detectors 227a and 227b of the fork-side sensors 227 transmit the timing at which a long distance is switched to a short distance and the timing at which a short distance is switched to a long distance to the controller 90 when they pass through the position above the substrate W. Further, during the scan of the transfer device 22, the controller 90 recognizes the position of the fork 223, i.e., the positions (three-dimensional coordinates) of the detectors 227a and 227b, based on the movement of the arms 222 of the transfer device 22. The controller 90 associates the timing at which the fork-side sensors 227 detect information with the recognized positions of the detectors 227a and 227b, thereby detecting four locations Wd (see white stars in FIG. 5B) on the outer edge of the substrate W.

Further, the fork-side sensors 227 do not necessarily detect the outer edge of the substrate W as a transfer object based on the displacement amount detected by the optical displacement sensor. For example, the fork-side sensors 227 may detect the edge of the transfer object by recognizing a change in light intensity (intensity of light reflected from the target after irradiating the target with light from the fork-side sensors 227). In short, in the teaching method, the location where the height of the transfer object changes can be detected based on the change in the measurement value of the sensor applied to the fork-side sensors 227 (e.g., the change in light intensity). Further, the type of the fork-side sensors 227 is not particularly limited, and may be an on-off sensor that detects the transfer object by transmitting or blocking detection light, a capacitance sensor that detects a change in a capacitance when it passes through a position above the substrate W, or the like. Alternatively, the fork-side sensor 227 may be an infrared sensor, an ultrasonic sensor, a radar, a camera, or the like. Further, in the substrate processing system 1, the position and number of the fork-side sensors 227 are not particularly limited. For example, if one camera is provided as the fork-side sensor 227 and images the transfer object, it is possible to calculate the center position of the transfer object.

Then, the controller 90 calculates the center position Wo of the substrate W (see the black star in FIG. 3B) using the positions of the four points Wd detected by the fork-side sensors 227. For example, the controller 90 can calculate normal lines directed radially inward from the detected four locations Wd, and calculate the location where the normal lines intersect with each other as the center position Wo of the substrate W.

Referring back to FIG. 1, the two load-lock modules 30 of the substrate processing system 1 are disposed between the vacuum transfer module 20 and the atmospheric transfer module 40, and the inner atmosphere thereof is switched between an atmospheric atmosphere and a vacuum atmosphere. Specifically, each load-lock module 30 includes a container 31 that accommodates the substrate W, and a placing table 32 on which the substrate W is placed in the container 31. For example, the placing table 32 has a groove (not shown) into which the fork 223 of the vacuum transfer device 22 and a fork 423 of an atmospheric transfer device 42 to be described later can enter, and the substrate W is received and delivered by moving the forks 223 and 423 back and forth and up and down. The placing table 32 may include lifters, similarly to the substrate support 12 of the processing module 10.

Each load-lock module 30 includes a connection part 33 on the vacuum transfer module 20 side and a connection part 35 on the atmospheric transfer module 40 side. The connection parts 33 and 35 have therein gate valves (not shown) for opening and closing the opening of the container 31. Each load-lock module 30 communicates with the vacuum transfer module 20 by opening the gate valve of the connection part 33 in a vacuum atmosphere state. Each load-lock module 30 communicates with the atmospheric transfer module 40 by opening the gate valve of the connection part 35 in an atmospheric state.

The inner atmosphere of the atmospheric transfer module 40 of the substrate processing system 1 is maintained in an atmospheric atmosphere. The atmospheric transfer module 40 includes a transfer chamber 41 connected to the load-lock modules 30, and an atmospheric transfer device 42 for transferring the substrate W in the transfer chamber 41. In the atmospheric transfer module 40, downflow of clean air is generated in the transfer chamber 41. Further, an aligner 43 for adjusting misalignment and a circumferential position of the substrate W is disposed on the lateral side of the atmospheric transfer module 40.

Further, the plurality of load ports 50 are provided on the wall surface of the atmospheric transfer module 40. A carrier C containing a substrate W or an empty carrier C is attached to each load port 50. The carrier C may be, e.g., a front opening unified pod (FOUP) or the like. The carrier C accommodating a ring R that is an example of a transfer object may be attached to each load port.

Similarly to the vacuum transfer device 22, the atmospheric transfer device 42 includes a base 421 that is movable in the longitudinal direction of the transfer chamber 41, a plurality of arms 422 that can rotate, extend and contract, and move up and down with respect to the base 421, and a fork (end effector) 423 disposed at the arm 422 on the distal end side. The atmospheric transfer device 42 supports the substrate W on the upper surface of the fork 423, and transfers the substrate W by appropriately operating the base 421 and the arms 422. Although FIG. 1 illustrates the atmospheric transfer device 42 including two forks 423, the present disclosure is not limited thereto, and the atmospheric transfer device 42 may have a configuration including one or three or more forks 423.

The atmospheric transfer device 42 transfers the substrate W between each load-lock module 30 and the atmospheric transfer module 40 by opening and closing the gate valve of each connection part 35. Further, the atmospheric transfer device 42 transfers the substrate W between the aligner 43 and the atmospheric transfer module 40. Further, the atmospheric transfer device 42 transfers the substrate W between each carrier C attached to each load port 50 and the atmospheric transfer module 40.

The controller 90 is a computer including a processor 91, a memory 92, an input/output interface (not shown), and a communication interface (not shown). The processor 91 is combination of one or more of a central processing unit (CPU), a graphics processing unit (GPU), an application specific integrated circuit (ASIC), a field-programmable gate array (FPGA), a circuit including a plurality of discrete semiconductors, and the like, and executes the program stored in the memory 92. The memory 92 includes a main storage device such as a semiconductor memory, and an auxiliary storage device such as a disk or a semiconductor memory (flash memory).

For example, the controller 90 controls the atmospheric transfer device 42 to transfer an unprocessed substrate W of the carrier C attached to the load port 50 to the aligner 43 so that the misalignment and the position of the substrate W can be adjusted, and to transfer the substrate W of the aligner 43 to one of the load-lock modules 30. After the load-lock module 30 containing the substrate W is depressurized, the controller 90 controls the vacuum transfer device 22 to take out the substrate W and transfers the substrate W to one of the processing modules 10 via the vacuum transfer module 20. Thereafter, the controller 90 performs substrate processing in each processing module 10 into which the substrate W is loaded. After the substrate processing, the controller 90 transfers the substrate W of one processing module 10 to the carrier C for accommodating a processed substrate W in a reverse order of the above-described sequence.

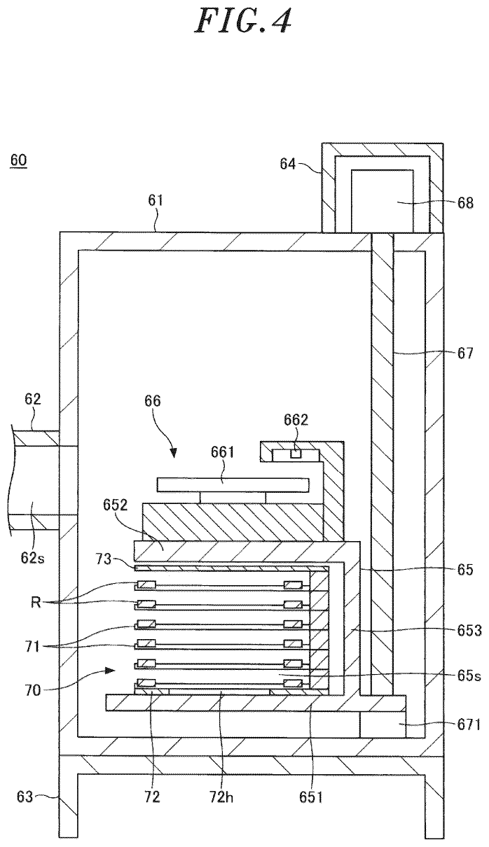

Further, in the substrate processing system 1 according to the embodiment, the storage module 60 accommodating a plurality of rings R as consumable members is connected to the vacuum transfer module 20. The storage module 60 includes a storage housing 61, and a connection part 62 that connects the storage housing 61 and the vacuum transfer module 20. The connection part 62 has therein a passage 62s (see FIG. 4) communicating with the space of the storage housing 61, and a gate valve (not shown) for opening/closing the passage 62s. The ring R can be transferred to the storage module 60 through the connection part 62 by opening the gate valve, and the inner atmosphere of the storage module 60 can be depressurized to an appropriate vacuum atmosphere by closing the gate valve. In FIG. 1, the storage module 60 is installed at the longitudinal end of the vacuum transfer module 20 (the end opposite to the end facing the load-lock modules 30). However, the present disclosure is not limited thereto, and the storage module 60 may be installed on the lateral side of any one of the multiple processing modules 10, for example.

In the substrate processing system 1, the ring R is unloaded from the storage module 60 and loaded into an appropriate processing module 10 by the vacuum transfer device 22, and the ring R is received and delivered to the substrate support part 12. Further, when the ring R in the processing module 10 is consumed by the substrate processing, in the substrate processing system 1, the vacuum transfer device 22 enters the processing module 10 to receive a used ring R, transfers the ring R to the storage module 60, and stores it in an empty tray.

FIG. 4 is a side cross-sectional view showing the storage module 60 of the substrate processing system 1. As shown in FIG. 4, in the storage module 60, a storage housing 61 is installed on a frame 63, and a sub-housing 64 is disposed on the storage housing 61. Further, the storage module 60 may include, outside the storage housing 61, a gas supply part (not shown) for supplying an inert gas such as N₂ gas, and an exhaust part (not shown) for exhausting a gas. A pressure in the storage module 60 can be adjust to an appropriate pressure by exhausting the gas in the storage housing 61 using the exhaust part while supplying the inert gas using the gas supply part. The space between the storage housing 61 and the sub-housing 64 is airtightly sealed. Therefore, the sub-housing 64 may be maintained in an atmospheric atmosphere.

A cassette 70 storing a plurality of rings R is set in the storage housing 61. The storage housing 61 has therein a basket 65 where the cassette 70 is set, and an aligner 66 installed above the basket 65. The basket 65 has a bottom portion 651 that supports the cassette 70, a ceiling portion 652 that is disposed above the bottom portion 651 and supports the aligner 66, and a sidewall 653 that extends vertically upward from the bottom portion 651 and supports the ceiling portion 652. The space surrounded by the bottom portion 651, the ceiling portion 652, and the sidewall 653 serves as a storage space 65s for storing the cassette 70.

In the storage module 60, the cassette 70 is set in the storage space 65s of the basket 65 by an operator. A door (not shown) for loading/unloading the cassette 70 from the outside is disposed at an appropriate position in the storage housing 61. Further, a movable body 671 of a ball screw mechanism 67 is connected to the bottom portion 651 of the basket 65.

The ball screw mechanism 67 extends vertically (in Z-axis direction) between the upper surface and the bottom surface of the storage housing 61, and is connected to a motor 68 in the sub-housing 64 through the ceiling of the storage housing 61. The ball screw mechanism 67 is rotated by driving the motor 68, and moves the basket 65 in the vertical direction via the movable body 671.

The aligner 66 has a placing table 661 on which the ring R is placed, and a detection part 662 that detects the ring R on the placing table 661. For example, the placing table 661 has a rotation mechanism (not shown) that rotates the placed ring R in a clockwise direction or a counterclockwise direction. For example, the detection part 662 may be an optical sensor in which a light emitting part and a light receiving part are combined.

The aligner 66 detects an orientation flat (OF) or a notch of the ring R using the detection part 662 while rotating the placing table 661, and transmits the detection information to the controller 90. The controller 90 recognizes the orientation flat of the ring R based on the fact that the amount of light in the detected detection information changes depending on the presence or absence of the orientation flat. The detection part 662 may use another optical sensor such as a camera or the like. In the case of using a camera, the controller 90 calculates the position information of the ring R by applying a well-known image processing technique to the image captured by the camera.

Based on the detected position and circumferential position (the direction of the orientation flat) of the ring R, the controller 90 controls the aligner 66 and the vacuum transfer device 22 to adjust the position and orientation of the ring R and controls the vacuum transfer device 22 to hold it. Accordingly, the vacuum transfer device 22 can hold and transfer the ring R to the processing module 10 with high accuracy.

The cassette 70 set in the storage space 65s of the basket 65 is a storage container that is opened on one side and can store multiple rings R along the vertical direction. The cassette 70 is set in the basket 65 by an operator such that the opened side faces the connection part 62 of the storage module 60.

The cassette 70 according to the embodiment is assembled by stacking multiple trays 71, each for supporting a ring R, in the vertical direction. The multiple trays 71 have the same thickness, and the rings R can be arranged at equal intervals in the vertical direction. Each tray 71 has a U-shaped support plate that supports the bottom surface and both sides in the width direction of the ring R, for example, and the fork 223 of the vacuum transfer device 22 enters the space in the support plate to support the ring R on the upper surface of the fork 223.

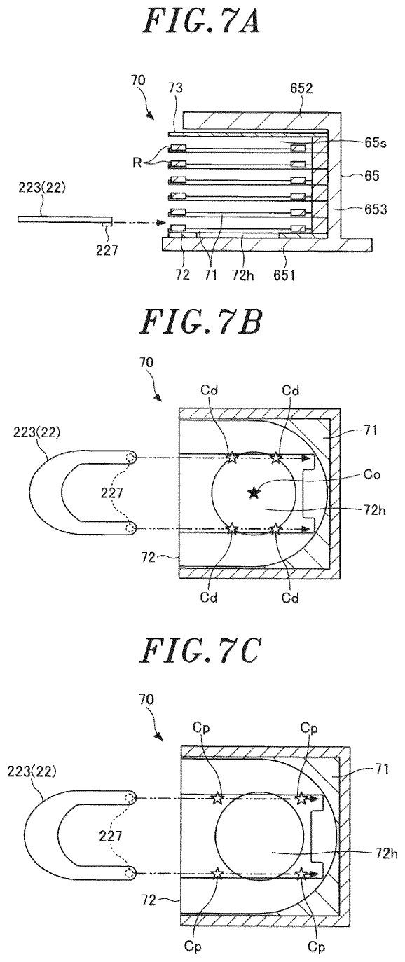

Further, the cassette 70 has a bottom plate 72 that supports the lowermost tray 71. A circular opening 72h (see also FIG. 7B) is formed at the center of the bottom plate 72. For example, the opening 72h has a diameter greater than the width of the pair of support plate portions 225 of the fork 223 and smaller than the inner diameter of the ring R. Further, the cassette 70 has a top plate 73 that is stacked on the top surface of the uppermost tray 71 to cover the ring R. The top plate 73 is a flat plate with no opening.

The cassette 70 is guided by a positioning device (not shown), such as a low protrusion or a shallow groove, disposed at the bottom portion 651 of the basket 65, and is set in the basket 65 by an operator. However, the positioning device has a slight gap between the cassette 70 and itself, and the cassette 70 is not necessarily positioned with respect to the basket 65 with high accuracy. In other words, the storage module 60 may be set in the basket 65 in a state where the entire cassette 70 is misaligned.

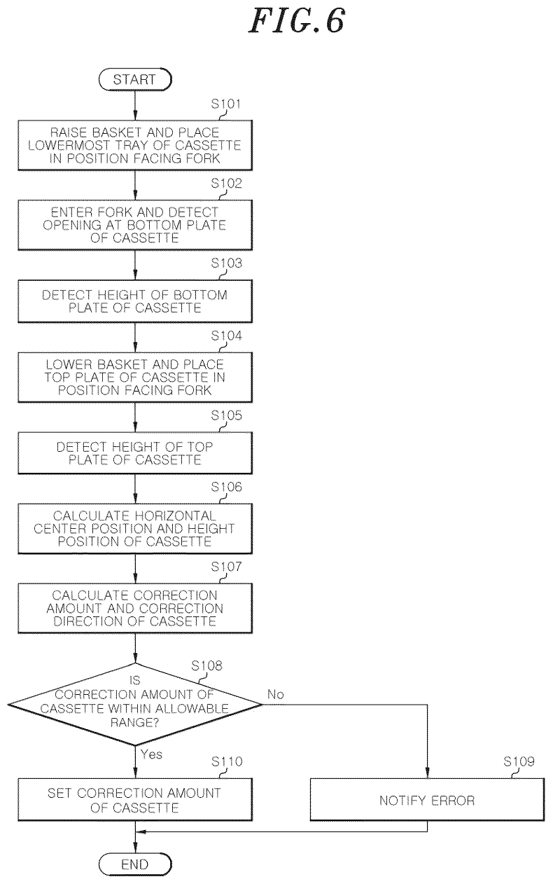

Therefore, the substrate processing system 1 according to the embodiment is configured to perform a teaching method for teaching the transfer position of the cassette 70 to the vacuum transfer device 22 under the control of the controller 90 whenever the cassette 70 of the storage module 60 is set. Hereinafter, the teaching method will be described with reference to FIGS. 5 and 6. FIG. 5 is a flowchart showing a process flow of the teaching method according to the embodiment. FIG. 6 is a flowchart showing a process flow of a cassette position detection process of the teaching method.

As shown in FIG. 5, in the teaching method, the controller 90 performs an aligner position detection process (step S1) of detecting the position of the aligner 66 of the storage module 60 at the time of starting up the system or during maintenance of the storage module 60. In the teaching method, the aligner position detection process is performed only once, and is not performed during replacement of the cassette 70. Accordingly, it is possible to quickly perform the operation of replacing the cassette 70.

In the aligner position detection process, the controller 90 moves the vacuum transfer device 22 above the aligner 66 of the storage module 60, and detects the outer edge of the placing table 661 of the aligner 66 at multiple locations (four locations) using the fork-side sensors 227 (see also FIG. 3B). The controller 90 recognizes the positions of the multiple locations based on the detection timing of the outer edge by the fork-side sensors 227 and the position of the fork 223 of the vacuum transfer device 22 recognized in the controller 90. Then, the controller 90 calculates the center position (X coordinate, Y coordinate) of the placing table 661 using the recognized positions of the outer edge of the placing table 661.

Further, when the vacuum transfer device 22 enters, the controller 90 performs distance measurement using the fork-side sensors 227 (displacement sensor) at the multiple (four) positions facing the placing surface of the placing table 661. The controller 90 calculates the height of the placing surface of the placing table 661 based on the result of the distance measurement by the fork-side sensors 227 and the position of the fork 223 of the vacuum transfer device 22 recognized in the controller 90. In this case, the controller 90 calculates the average value of the heights of the multiple calculated positions and sets the average value as the height (Z coordinate) of the aligner 66. Accordingly, the controller 90 can set the calculated three-dimensional coordinates of the aligner 66 as the reference position of the storage module 60.

After the system is started or after the maintenance of the storage module 60, the controller 90 monitors the setting of the cassette 70 in the storage module 60 (step S2). The operator opens the door of the storage module 60 and sets the cassette 70 in the storage space 65s of the basket 65. The controller 90 may detect and recognize the setting of the cassette 70 using a sensor (not shown) disposed at the basket 65, or may recognize the setting of the cassette 70 by an operator's operation of setting the cassette 70.

When the controller 90 recognizes the setting of the cassette 70 in the storage module 60 (step S2: YES), the controller 90 automatically starts a cassette position detection process (step S3) for detecting the position of the cassette 70. In the cassette position detection process, the controller 90 controls individual components of the vacuum transfer device 22 and the storage module 60 to sequentially execute the process flow of steps S101 to S110 shown in FIG. 6.

Specifically, the controller 90 first operates the ball screw mechanism 67 to raise the basket 65 and place the lowermost tray 71 of the cassette 70 in a position facing the connection part 62 (step S101). In this case, the controller 90 controls the movement of the basket 65 using the reference position of the aligner 66 acquired in the aligner position detection process (step S1 in FIG. 5). In other words, since the controller 90 recognizes the reference position of the aligner 66 and the size of the basket 65, the controller 90 can calculate the reference position of the lowermost tray 71 of the cassette 70 set in the basket 65. Therefore, the controller 90 can move the basket 65 based on the reference position of the lowermost tray 71.

Next, the controller 90 controls the fork 223 of the vacuum transfer device 22 to enter the storage housing 61 and detects the position of the inner edge constituting the opening 72h at the bottom plate 72 of the cassette 70 (step S102). The inner edge of the opening 72h can be detected by applying the above-described method of scanning using the fork-side sensors 227.

FIG. 7A is a side view showing the operation of the fork-side sensors 227 to detect the bottom plate 72. FIG. 7B is a plan view showing the operation of the fork-side sensors 227 to detect the opening 72h of the bottom plate 72. FIG. 7C is a plan view showing the operation of the fork-side sensors 227 to detect the height position of the bottom plate 72. As shown in FIGS. 7A and 7B, the controller 90 slides the fork 223 horizontally and scans the fork-side sensors 227. The controller 90 recognizes the positions of the four points Cd on the inner edge based on the timing of detection of the inner edge of the opening 72h by the fork-side sensors 227 and the position of the fork 223 of the vacuum transfer device 22 recognized in the controller 90 (see the white stars in FIG. 7B). Accordingly, the controller 90 can calculate the coordinates (X coordinate, Y coordinate) of the center position Co of the opening 72h using the recognized positions of the four points Cd on the inner edge of the opening 72h (see the black stars in FIG. 7B).

Further, the controller 90 detects the height position of the bottom plate 72 of the cassette 70 when the fork 223 of the vacuum transfer device 22 is retracted (step S103). The height position of the bottom plate 72 is detected by measuring the distance using the fork-side sensors 227 at four points Cp facing the upper surface of the bottom plate 72 (see the white stars in FIG. 7C). The controller 90 calculates the height position of the bottom plate 72 based on the result of the distance measurement by the fork-side sensors 227 and the position of the fork 223 of the vacuum transfer device 22 recognized in the controller 90. The four points Cp of the bottom plate 72 are preferably set at two points on the rear side of the opening 72h in the approaching direction and two points on the front side of the opening 72h in the approaching direction.

After the fork 223 of the vacuum transfer device 22 is retracted from the storage housing 61, the controller 90 operates the ball screw mechanism 67 to lower the basket 65 and place it at a position where the top plate 73 of the cassette 70 faces the connection part 62 (step S104). In this case as well, the controller 90 controls the movement of the basket 65 using the reference position of the aligner 66 acquired in the aligner position detection process (step S1 in FIG. 5).

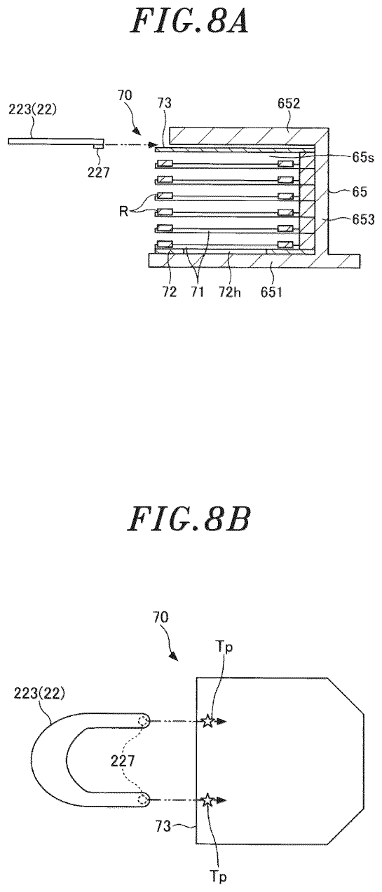

Then, the controller 90 controls the fork 223 of the vacuum transfer device 22 to enter the storage housing 61 again, and detects the height position of the top plate 73 of the cassette 70 (step S105). As shown in FIGS. 8A and 8B, a gap that allows the fork 223 to enter sufficiently may not exist between the ceiling portion 652 of the basket 65 and the top plate 73 of the cassette 70. Hence, in detecting the height position of the top plate 73, the controller 90 does not cause the fork 223 to enter the gap between the ceiling portion 652 and the top plate 73, and performs distance measurement using the fork-side sensors 227 for two points Tp of the top plate 73 that are exposed on the front side in the approaching direction of the fork 223. The controller 90 calculates the height position of the top plate 73 based on the results of the distance measurement by the fork-side sensors 227 and the position of the forks 223 of the vacuum transfer device 22 recognized in the controller 90. The controller 90 calculates the average value of the calculated height positions of the two points Tp, and sets the average value as the height (Z coordinate) of the top plate 73.

When the detection of the bottom plate 72 and top plate 73 of the cassette 70 is completed, the controller 90 calculates the horizontal center position of the cassette 70 based on the detection results, and calculates the height position of the cassette 70 (step S106). For example, the controller 90 uses the center position of the opening 72h of the bottom plate 72 for the calculation of the horizontal position. Further, the controller 90 calculates the height position of the cassette 70 by equally dividing the recognized height positions of the bottom plate 72 and the top plate 73.

Then, the controller 90 compares the calculated three-dimensional coordinates of the cassette 70 with the pre-obtained reference position of the cassette 70, and calculates the correction amount and correction direction of the set cassette 70 (step S107). The reference position of the cassette 70 can be obtained in advance, for example, by using the reference position of the aligner 66 acquired in the aligner position detection process.

Further, the controller 90 determines whether or not the calculated correction amount is within an allowable range (step S108). If the correction amount is not within the allowable range, it is determined that the cassette 70 is set while being considerably misaligned with respect to the target set position in the basket 65. Therefore, if the correction amount is not within the allowable range (step S108: NO), the controller 90 notifies an error indicating the misalignment of the cassette 70 via the connected user interface (step S109).

On the other hand, if the correction amount is within the allowable range, it is determined that the cassette 70 is appropriately set with respect to the basket 65 (within a range that the ring R can be held with high accuracy even if there is misalignment). If the correction amount is within the allowable range (step S108: YES), the controller 90 sets the calculated correction amount of the cassette 70 (step S110).

By performing the above teaching method, the substrate processing system 1 can control the vacuum transfer device 22 while considering the correction amount and the correction direction of the cassette 70 that are taught with respect to the reference position of the cassette 70 at the time of transferring the ring R as a consumable member by the vacuum transfer device 22. Accordingly, the vacuum transfer device 22 can hold the ring R with high accuracy, and can load/unload the ring R while avoiding interference between the ring R and the storage module 60, for example. Further, the vacuum transfer device 22 can transfer the ring R to a target processing module 10 with high accuracy. Further, in the substrate processing system 1, the basket 65 of the storage module 60 can be raised and lowered in the vertical direction (Z-axis direction) based on the calculated correction amount at the time of loading/unloading the ring R into/from the storage module 60. In other words, in the substrate processing system 1, the ring R can be loaded/unloaded with high accuracy by performing horizontal correction (X-axis direction, Y-axis direction) in the vacuum transfer device 22 and vertical correction in the storage module 60.

The teaching method and the substrate processing system 1 of the present disclosure are not limited to the above embodiment, and can be variously modified. For example, in the above embodiment, the teaching method applied to the case of transferring the ring R by the vacuum transfer device 22 has been described. However, the teaching method of the present disclosure can also be applied to the case of transferring the ring R while setting the cassette 70 containing the ring R in the atmospheric transfer module 40. In this case, the atmospheric transfer module 40 where the cassette 70 is set corresponds to the storage module.

Further, in the teaching method according to the embodiment, a plurality of different positions (the bottom plate 72 and the top plate 73) in the height direction of the cassette 70 are detected by the fork-side sensors 227, and the transfer position of the cassette 70 is detected. However, in the teaching method, one position of the cassette 70 may be detected by the fork-side sensors 227, and the transfer position of the cassette 70 may be detected. Accordingly, the teaching method can be completed in a short period of time.

Further, in the teaching method according to the embodiment, the fork-side sensors 227 are configured to detect the bottom plate 72 or the top plate 73 of the cassette 70. However, in the teaching method, another part of the cassette 70 may be detected by the fork-side sensors 227. Another part of the cassette 70 may be, e.g., the tray 71 of the cassette 70 (such as the end of the U-shaped support). Alternatively, the cassette 70 may have a protrusion protruding toward the connection part 62 to be detected by the fork-side sensors 227.

The technical ideas and effects of the present disclosure described in the above embodiments will be described below.

According to a first aspect of the present disclosure, a teaching method for teaching a transfer position of a consumable member in the cassette 70 included in the substrate processing system 1, the substrate processing system 1 having the transfer device (the vacuum transfer device 22) for transferring the consumable member (the ring R) and the storage module 60 where the cassette 70 capable of storing a plurality of consumable members is set, the method including the steps of: (A) recognizing setting of the cassette 70 in the storage module 60; and (B) after the step (A), detecting the cassette 70 by the sensors (the fork-side sensors 227) of the transfer device, and calculating three-dimensional coordinates of the cassette 70 based on detection information of the sensor.

In accordance with the above description, in the teaching method, the transfer position of the cassette 70 set in the storage module 60 can be efficiently and accurately taught using the sensors (the fork-side sensors 227) of the transfer device (the vacuum transfer device 22). In particular, in the teaching method, the transfer position of the cassette 70 is taught when the cassette 70 is set in the storage module 60, so that it is possible to easily absorb errors at the time of setting the cassette 70 or machine differences of the cassette 70 itself. Further, the transfer device can hold the consumable member (the ring R) with high accuracy by using the taught transfer position, and can stably load/unload the consumable member into/from the storage module 60.

Further, the transfer device (the vacuum transfer device 22) has the fork 223 that supports the consumable member (the ring R), and the sensors (the fork-side sensors 227) are disposed at the tip ends of the fork 223. In the step (B), the fork 223 moves forward relative to the cassette 70, and the position of the cassette 70 is directly detected by the sensors. Accordingly, in the teaching method, the sensors can directly detect the position of the cassette 70 by moving the fork 223, and the teaching accuracy of the transfer position can be further improved.

Further, the cassette 70 includes the bottom plate 72 having the opening 72h. In step (B), the sensors (the fork-side sensors 227) detect multiple positions of the inner edge of the bottom plate 72 that constitutes the opening 72h, and the center position Co of the opening 72h is calculated based on the multiple positions of the inner edge of the bottom plate 72. In the teaching method, the horizontal position of the cassette 70 can be simply obtained by detecting the inner edge of the opening 72h of the bottom plate 72 with the sensors.

Further, in step (B), the height position of the bottom plate 72 of the cassette 70 is detected by the sensors (the fork-side sensors 227). Accordingly, in the teaching method, the height position of the cassette 70 can be easily measured. In particular, in the teaching method, the three-dimensional coordinates of the cassette 70 can be quickly obtained through a step of detecting the opening 72h of the bottom plate 72 of the cassette 70.

Further, in the step (B), the height position of the top plate 73 of the cassette 70 is detected by the sensors (the fork-side sensors 227). Accordingly, in the teaching method, the height position of the cassette 70 can be simply obtained.

Further, in the step (B), the sensors (the fork-side sensors 227) detect multiple positions of the cassette 70 which have different heights. Accordingly, in the teaching method, the height position of the cassette 70 can be calculated with higher accuracy.

Further, the storage module 60 has the aligner 66 for adjusting the misalignment and/or the position in the rotational direction of the consumable member (the ring R). Prior to the step (A), the sensors (the fork-side sensors 227) of the transfer device (the vacuum transfer device 22) detect the reference position of the aligner 66. In step (B), the positions of the transfer device and the cassette 70 are adjusted based on the reference position of the aligner 66. In the teaching method, by using the reference position of the aligner 66, the transfer device or the cassette 70 can be moved with high accuracy, which makes it possible to avoid interference between the transfer device and the cassette 70.

The sensor (the fork-side sensor 227) is a displacement sensor for measuring the distance from the transfer device (the vacuum transfer device 22) to the opposing object. Accordingly, in the teaching method, both the horizontal position and the vertical position of the cassette 70 can be successfully detected.

The consumable member is the ring R disposed around the substrate W during substrate processing. Accordingly, in the teaching method, the ring R can be accurately held by controlling the transfer device (vacuum transfer device 22) based on the taught transfer position.

According to a second aspect of the present disclosure, the substrate processing system 1 includes the transfer device (the vacuum transfer device 22) for transferring a consumable member (the ring R), the storage module 60 where the cassette 70 capable of storing a plurality of consumable members is set, and the controller 90. The controller 90 performs (A) recognizing the setting of the cassette 70 in the storage module 60; and (B) after said (A), detecting the cassette 70 using the sensors (the fork-side sensors 227) of the transfer device and calculating the three-dimensional coordinates of the cassette 70 based on the detection information of the sensors, and recognizes the transfer position of the consumable member in the cassette 70 based on the three-dimensional coordinates of the cassette 70. In this case as well, the substrate processing system 1 can stably load/unload the consumable member into/from the storage module.

The teaching method and the substrate processing system 1 according to the embodiments of the present disclosure is illustrative in all respects and are not restrictive. The above-described embodiment may be changed or modified in various forms without departing from the scope of the appended claims and the gist thereof. The above-described embodiment may include other configurations without contradicting each other and may be combined without contradicting each other.

1. A teaching method for teaching a transfer position of a consumable member in a cassette included in a substrate processing system, the substrate processing system having a transfer device configured to transfer the consumable member, and a storage module where the cassette accommodating a plurality of the consumable members is set;
the teaching method comprising the steps of:
(A) recognizing setting of the cassette in the storage module; and
(B) after the step (A), detecting the cassette by a sensor of the transfer device and calculating three-dimensional coordinates of the cassette based on detection information of the sensor.

2. The teaching method of claim 1, wherein the transfer device has a fork that supports the consumable member,
the sensor is disposed at a tip end of the fork;
in the step (B), the position of the cassette is directly detected by the sensor by moving the fork forward relative to the cassette.

3. The teaching method of claim 2, wherein the cassette includes a bottom plate having an opening and an inner edge of the bottom plate constitutes the opening, and
in the step (B), multiple positions of an inner edge of the bottom plate are detected by the sensor, and a center position of the opening is calculated based on the multiple positions of the inner edge of the bottom plate.

4. The teaching method of claim 2, wherein in the step (B), a height position of the bottom plate of the cassette is detected by the sensor.

5. The teaching method of claim 2, wherein in the step (B), a height position of a top plate of the cassette is detected by the sensor.

6. The teaching method of claim 2, wherein in the step (B), multiple positions of the cassette which have different heights are detected by the sensor.

7. The teaching method of claim 1, wherein the storage module has an aligner that adjusts misalignment and/or a position in a rotational direction of the consumable member,
a reference position of the aligner is detected by the sensor of the transfer device before the step (A), and
the positions of the transfer device and the cassette are adjusted based on the reference position of the aligner in the step (B).

8. The teaching method of claim 2, wherein the storage module has an aligner that adjusts misalignment and/or a position in a rotational direction of the consumable member,
a reference position of the aligner is detected by the sensor of the transfer device before the step (A), and
the positions of the transfer device and the cassette are adjusted based on the reference position of the aligner in the step (B).

9. The teaching method of claim 3, wherein the storage module has an aligner that adjusts misalignment and/or a position in a rotational direction of the consumable member,
a reference position of the aligner is detected by the sensor of the transfer device before the step (A), and
the positions of the transfer device and the cassette are adjusted based on the reference position of the aligner in the step (B).

10. The teaching method of claim 1, wherein the sensor is a displacement sensor that measures a distance from the transfer device to an opposing object.

11. The teaching method of claim 2, wherein the sensor is a displacement sensor that measures a distance from the transfer device to an opposing object.

12. The teaching method of claim 3, wherein the sensor is a displacement sensor that measures a distance from the transfer device to an opposing object.

13. The teaching method of claim 1, wherein the consumable member is a ring disposed around a substrate during substrate processing.

14. The teaching method of claim 2, wherein the consumable member is a ring disposed around a substrate during substrate processing.

15. The teaching method of claim 3, wherein the consumable member is a ring disposed around a substrate during substrate processing.

16. A substrate processing system comprising:
a transfer device configured to transfer a consumable member;
a storage module where a cassette accommodating a plurality of the consumable members is set; and
a controller,
wherein the controller performs:
(A) recognizing the setting of the cassette in the storage module; and
(B) after said (A), detecting the cassette using a sensor of the transfer device and calculating three-dimensional coordinates of the cassette based on detection information of the sensor, and
recognizes a transfer position of the consumable member in the cassette based on the three-dimensional coordinates of the cassette.
